(19) United States
(12) Patent Application Publication
(10) Pub. No.: US 2007/0138513 A1
(43) Pub. Date: Jun. 21, 2007

(54) INPUT DEVICE

(75) Inventors: Tadamitsu Sato, Fukushima-ken (JP); Shuzo Ono, Fukushima-ken (JP)

Correspondence Address: BRINKS HOFER GILSON & LIONE, P.O. BOX 10395, CHICAGO, IL, 60610, US

(73) Assignee: ALPS ELECTRIC CO., LTD., Tokyo (JP)

(21) Appl. No.: 11/612,351

(22) Filed: Dec. 18, 2006

(30) Foreign Application Priority Data
Dec. 19, 2005 (JP) 2005-364670

(51) Int. Cl. H01L 29/768

(52) U.S. Cl. 257/239

(57) ABSTRACT

Provided is an input device capable of driving X electrodes and Y electrodes provided in a plurality of detection regions by a common X driver and a common Y driver and detecting a coordinate of an operation body in the detection regions by a simple circuit configuration.

By the common X driver 11, X electrodes X1 to X6 in a first detection region 1 and X electrodes X11 to X16 in a second detection region 2 are simultaneously selected and supplied with a potential. By a common Y driver 12, Y electrodes Y1 to Y8 in the first detection region 1 and Y electrodes Y11 to Y18 in the second detection region 2 are simultaneously selected and supplied with a potential. A first detection electrode S1 is provided in the first detection region 1 and a second detection electrode S2 is provided in the second detection region 2. As a result, it is possible to identify whether a finger contacts the first detection region 1 or the second detection region 2 and obtain coordinate information of a contact position of the finger in the regions.

This patent document claims the benefit of Japanese Patent Application No. 2005-364670, filed on Dec. 19, 2005, which is hereby incorporated by reference.

### BACKGROUND

1. Field

The present embodiments relate to an input device divided into a plurality of detection regions.

2. Related Art

Patent Document 1 discloses a capacitance type coordinate input device, which includes a plurality of X electrodes and Y electrodes arranged in a matrix.

In this coordinate input device, the plurality of X electrodes are arranged on one surface of a glass substrate and the plurality of Y electrodes are arranged the other surface thereof. The X electrodes and the Y electrodes are respectively arranged on the both surfaces of the glass substrate in the matrix and capacitances are formed between the X electrodes and the Y electrodes positioned below.

The X electrodes are connected to an oscillation circuit by a control unit and the Y electrodes are turned on such that a predetermined potential is applied to the X electrodes and the Y electrodes. When a finger contacts the coordinate input device, an electrostatic field between the X electrodes and the Y electrodes varies. A variation in voltage due to the variation in electrostatic field is output to the Y electrodes. The variation in voltage output from the Y electrodes is input to the control unit through an A/D converter. A voltage detector provided in the control unit specifies a position where the electrostatic field between the X electrodes and the Y electrodes varies on the basis of data from the A/D converter such that positional information of the contact position of the finger can be detected.

[Patent Document 1] Japanese Unexamined Patent Application Publication No. 8-137607

In the capacitance type input device, since the contact position of the finger needs to be detected as a position on the X-Y coordinate with precision, the interval between the adjacent X electrodes and the interval between the adjacent Y electrodes cannot widen. When the interval between the adjacent X electrodes is significantly wider than the contact area when the finger contacts an operation surface, the variation in electrostatic field between the X electrode and the Y electrode cannot be detected with precision when the finger contacts an intermediate position between the adjacent X electrodes. It is difficult to specify the contact position of the finger.

In order to widen the area of the detection region of the input unit, the number of the X electrodes and the number of the Y electrodes needs to increase as the area increases. Since the potential is given to the added X electrodes in sequence and the potential is given to the added Y electrodes in sequence, the configuration of a driving circuit for supplying the potential to the electrodes becomes complicated.

In order to provide the detection regions capable of detecting the contact of the finger in a plurality of regions of an information terminal such as a mobile phone, the substrates having the X electrodes and the Y electrodes needs to be separately provided and the driving circuits for respectively supplying the potential to the X electrodes and the Y electrodes needs to be separately provided to the substrates. When the driving circuits corresponding to the plurality of detection regions are provided, the number of circuits mounted in a small-sized apparatus increases and the configuration of a control circuit for individually controlling the driving circuits becomes complicated.

### SUMMARY

The present embodiments may obviate one or more of the limitations of the related art: For example, in one embodiment, an input device, which has the configuration of a driving circuit for supplying a potential to X electrodes and Y electrodes of a plurality of detection regions can be simplified. In another exemplary embodiment, a contact position of an operation body can be detected with precision in a plurality of detection regions. In another exemplary embodiment, an approaching position of the operation body can be detected in a wide area using the driving circuit having the simple configuration.

According to a first embodiment, an input device includes a plurality of detection regions, wherein an X electrode and a Y electrode which are insulated from and perpendicular to each other are provided in each of the detection regions. An X driver selects the X electrode in the plurality of detection regions and supplies a potential to the X electrode. A Y driver selects the Y electrode in the plurality of detection regions and supplies a potential to the Y electrode. Detection electrodes, which are independent of each other in the detection regions, are also provided in the input device. A variation in capacitance field between the X electrode supplied with the potential and the detection electrode and a variation in capacitance field between the Y electrode supplied with the potential and the detection electrode are individually detected in each of the detection regions by the detection electrode.

In one embodiment, the X electrode and the Y electrode may be provided in plural in at least one of the detection regions.

According to a second embodiment, an input device includes at least one of a first detection region and a second detection region. A plurality of X electrodes and Y electrodes, which are insulated from and perpendicular to each other, are provided in the first detection region and any one of an X electrode and a Y electrode is provided in the second detection region. An X driver selects the X electrode in the first detection region and supplies a potential to the X electrode. A Y driver selects the Y electrode in the second detection region and supplies a potential to the Y electrode. The X driver and Y driver are also provided in the input device. A potential is supplied from the X driver to the X electrode provided in the second detection region. A potential is applied from the Y driver to the Y electrode provided in the second detection region. Detection electrodes, which are independent of each other, are provided in the first detection region and the second detection region. A variation in capacitance field between the X electrode supplied with the potential and the detection electrode and a variation in capacitance field between the Y electrode supplied with the potential and the detection electrode are detected in the first detection region and a variation in capacitance field between the X electrode supplied with the potential and the detection electrode or a variation in capacitance field between the Y electrode supplied with the potential and the detection electrode is detected in the second detection region.

In one embodiment, the X electrode and the Y electrode may be provided in plural in at least one of the detection regions.

In one embodiment, the X electrodes or the Y electrodes are provided in different detection regions and are selected and supplied with a potential by a common X driver or a common Y driver. By the common driving circuit, for example, the common X driver or the common Y driver, the potential is selectively supplied to the X electrodes or the Y electrodes in the different detection regions. Since the detection electrodes are individually provided in the detection regions, it is possible to detect which detection region an operation body, which is a conductor, for example, a finger, approaches (contacts) and a coordinate position in the detection region by detecting a variation in voltage between the detection electrode and the selected X electrode or Y electrode.

In one embodiment, any X electrodes in the different detection regions may be simultaneously selected and supplied with a potential by the X driver. Any Y electrodes in the different detection region may be simultaneously selected and supplied with a potential by the Y driver.

For example, when the X electrodes in the different detection regions (any X electrode in one detection region and any X electrode in the other detection region) are simultaneously selected by the common X driver or the Y electrodes in the different detection region (any Y electrode in one detection region and any Y electrode in the other detection region) are simultaneously selected by the common Y driver, the number of electrodes selected by the X driver and the number of electrodes selected by the Y driver can be lower than the total number of electrodes and thus a circuit can be easily configured.

In one embodiment, the detection regions may be provided on different substrates or a same substrate. The X electrode may be provided on one surface of the substrate and the Y electrode may be provided on the other surface of the substrate. The detection electrodes may be provided on the one surface or the other surface.

When the plurality of detection regions are formed on the different substrates, it is possible to provide the detection regions at different positions in the same apparatus. When the plurality of detection regions are formed at adjacent positions, the plurality of detection regions may be used as a successive operation region and, as a result, the detection region operated by the finger can substantially widen.

In one embodiment, a data processing unit that generates positional information of a detection region, which an operation body of a conductor approaches, and an approaching position of the operation body in the detection region from the variation in capacitance field between the X electrode supplied with the potential and the detection electrode and the variation in capacitance field between the Y electrode supplied with the potential and the detection electrode may be provided.

In one embodiment, a switching unit may be provided. The switching unit sequentially selects the detection electrodes, which are independently provided in the detection regions, and connects the detection electrodes to the data processing unit.

When the detection electrodes, which are individually provided in the detection regions, are sequentially switched and connected to the data processing unit, it is possible to detect a contact position of the finger in the plurality of detection regions using the common data processing unit. In this embodiment, since the variation in voltage of one detection electrode is detected in the data processing unit, it is possible to simplify the configuration of the data processing unit. In one embodiment, the detection electrodes provided in the plurality of detection regions may be respectively connected to the common data processing unit and the data processing unit may detect the variation in voltage of all the detection electrodes to detect which detection region the finger contacts.

In one embodiment, the X electrodes in different detection regions may be connected to one another region or the Y electrodes in different detection regions may be connected to one another region.

For example, since the X electrodes or the Y electrodes are connected in the different detection regions, the application of the potential to the X electrode or the application of the potential to the Y electrode may be performed in one detection region and thus a connection structure that allocates a voltage applying operation of the X driver or the Y driver to the detection regions is unnecessary.

The present embodiments are not specifically limited to the above structures, functions, or examples. For example, all the plurality of detection regions may have the Y electrodes or all the plurality of detection regions may have the X electrodes. Individual detection electrodes may be provided in the detection regions. A potential may be supplied to the X electrodes in all the detection regions by a common X driver or a potential may be supplied to the Y electrodes in all the detection regions by a common Y driver. Alternatively, only the X electrodes are provided in the first detection region and only the Y electrodes are provided in the second detection region. Alternatively, only the Y electrodes are provided in the first detection region and only the X electrodes are provided in the second detection region, the individual detection electrodes are provided in the detection regions. In addition, the X driver or the Y driver may be commonly used in all the detection regions.

In one embodiment, for example, using a simple circuit configuration, it is possible to detect an approaching position or a contact position of an operation body in a plurality of detection regions and to detect the approaching/contact position of the operation body in the detection regions which are separated from one another or the approaching/contact position of the operation body in the operation regions having wide areas with precision.

### BRIEF DESCRIPTION OF THE DRAWINGS

FIG. 1 is a circuit block diagram showing an input device according to a first embodiment;

FIG. 2 is an enlarged explanatory view of detection regions in the input device;

FIG. 3 is an enlarged explanatory view of detection regions in an input device according to a second embodiment;

FIG. 4 is an enlarged explanatory view of detection regions in an input device according to a third embodiment;

FIG. 5 is an enlarged explanatory view of detection regions in an input device according to a fourth embodiment;

FIG. 6 is an enlarged explanatory view of the detection regions in the input device according to the second embodiment; and

FIG. 7 is a front view of a mobile phone in which the input device is mounted.

### DETAILED DESCRIPTION

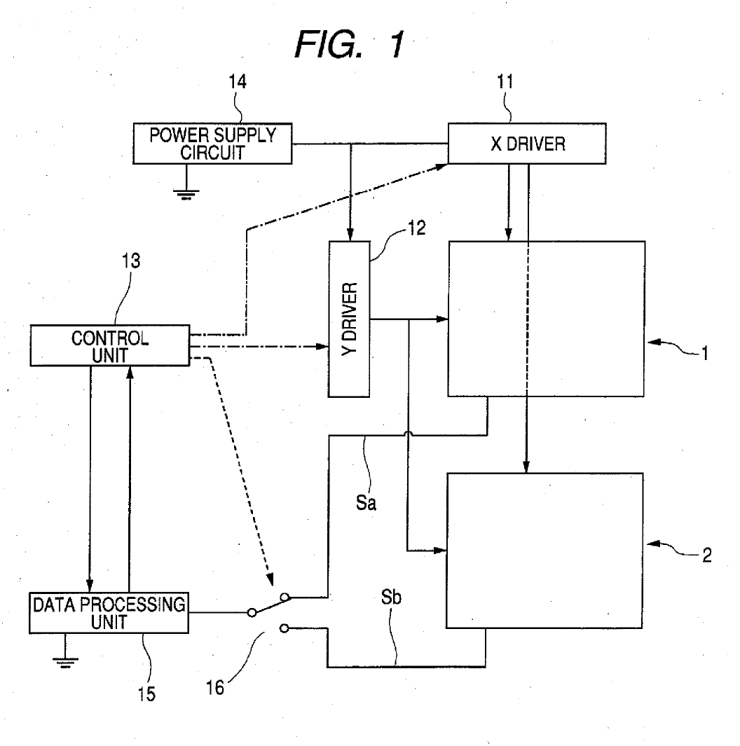

In one embodiment, as shown in FIG. 1, the input device has a first detection region 1 and a second detection region 2. The first detection region 1 and the second detection region 2 may be formed on different substrates or a single substrate in which the first detection region 1 and the second detection region 2 are defined. In this embodiment, the first detection region 1 and the second detection region 2 are formed on a single substrate and a flexible resin film substrate is used as the substrate. The resin film substrate includes an organic material substrate having a predetermined dielectric constant, such as polyethylenetelephtalate (PET) or polyimide.

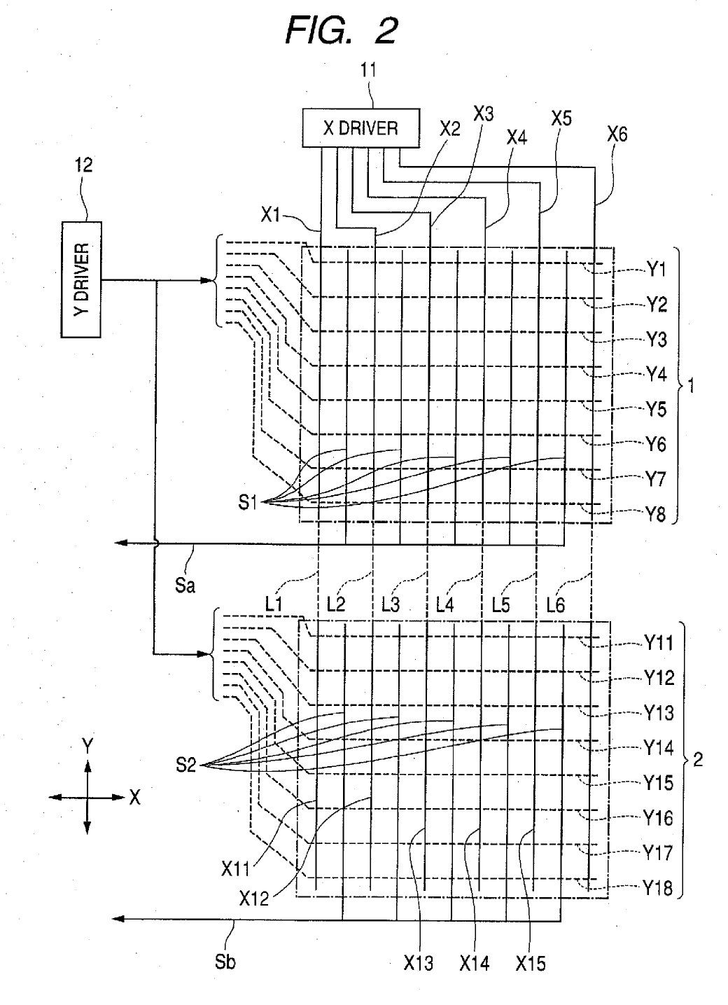

In one embodiment, as shown in FIG. 2, the first detection region 1 includes a plurality of X electrodes X1, X2, X3, X4, X5 and X6 that linearly extend on one surface (front surface of the drawing) of the substrate in parallel in a Y direction with a constant pitch. A plurality of Y electrodes Y1, Y2, Y3, Y4, Y5, Y6, Y7 and Y8 linearly extend on the other surface (rear surface of the drawing) of the substrate in parallel in the Y direction with a constant pitch. On the surface of the substrate on which the X electrodes are formed, first detection electrodes. S1 are provided. The detection electrodes S1 linearly extend in parallel in the Y direction with a constant pitch in an X direction and the individual detection electrodes S1 are located at the midpoints between adjacent X electrodes. The plurality of first detection electrodes S1 are connected to one another and connected to a first output line Sa.

In one embodiment, as shown in FIG. 2, the second detection region 2 includes parallel X electrodes X11, X12, X13, X14, X15 and X16 that are formed on one surface of the substrate and parallel Y electrodes Y11, Y12, Y13, Y14, Y15, Y16, Y17 and Y18 are formed on the other surface thereof. Second detection electrodes S2 are formed on one surface of the substrate. The second detection electrodes S2 linearly extend in the Y direction at midpoints between adjacent X electrodes. The plurality of second detection electrodes S2 are connected to one another and connected to a second output line Sb.

In one embodiment, the X electrodes, the Y electrodes and the detection electrodes S1 or S2 are insulated from one another in the first detection region 1 and the second detection region 2.

In one embodiment, the X electrodes, the Y electrodes, the first detection electrodes S1 and the second detection electrodes S2 are formed of a conductive material having low resistance, for example, silver or copper. Alternatively, the electrodes may be formed of a transparent electrode material such as ITO. When the transparent electrode material is used, a display device can be provided on the rear side of the first detection region 1 or the second detection region 2.

In one embodiment, the surfaces (front surfaces of the drawing) of the first detection region 1 and the second detection region 2 are covered with a cover. The cover is formed of a non-conductive material, for example, a thin synthetic resin plate. Alternatively, a part of a casing which configures a variety of electronic apparatuses such as a mobile terminal including a mobile phone and is made of synthetic resin may be used as the cover.

In one embodiment, capacitance is formed between the X electrodes and the detection electrodes S1 or S2 and capacitance is formed between the Y electrodes and the detection electrodes S1 or S2 in the first detection region 1 and the second detection region 2. A finger, which is an operation body or a conductor, contacts the cover that covers the first detection region 1 or the second detection region 2, capacitance is formed between the finger which is the conductor and the electrodes and thus electrostatic field between the X electrodes and the detection electrodes S1 or S2 varies. As a result, the capacitance between the X electrodes and the detection electrodes is reduced and the capacitance between the Y electrodes and the detection electrodes is reduced.

In one embodiment, in the first detection region 1 and the second detection region 2, the X electrodes and the Y electrodes are selected in sequence and supplied with a potential and a variation in potential difference between the X electrodes and the detection electrodes and a variation in potential difference between the Y electrodes and the detection electrodes are monitored such that a variation in capacitance between the electrodes may be detected.

In one embodiment, as shown in FIG. 2, the X electrodes X1, X2, X3, X4, X5 and X6 of the first detection region 1 and the X electrodes X11, X12, X13, X14, X15 and X16 of the second detection region 2 are individually connected via connection lines L1, L2, L3, L4, L5 and L6, respectively. For example, the X electrode X1 and the X electrode X11 are connected via the connection line L1, the X electrode X2 and the X electrode X12 are connected via the connection line L2, and the X electrodes X3 and X13, the X electrodes X4 and X14, the X electrodes X5 and X15, and the X electrodes X6 and X16 are individually connected via the connection lines L3, L4, L5 and L6, respectively.

The connection lines L1 to L6 are formed on the substrate on which the first detection region 1 and the second detection region 2 are formed. When the first detection region 1 and the second detection region 2 are respectively formed on different substrates, the connection lines L1 to L6 are formed on a flexible sheet that connect the both substrates.

In one embodiment, as shown in FIGS. 1 and 2, in the input device, an X driver 11 and a Y driver 12 are provided. The X driver 11 and the Y driver 12 are controlled by a control unit 13. A predetermined potential generated in a power supply circuit 14 is sequentially applied to the X electrodes X1 to X6 of the first detection region 1 by the X driver 11. Accordingly, the X electrode X1 of the first detection region 1 and the X electrode X11 of the second detection region 2 are simultaneously selected and supplied with the same potential. The X electrode X2 and the X electrode X12 are simultaneously selected and supplied with the same potential and the X electrode X3 and the X electrode X13 are simultaneously selected and supplied with the same potential. With respect to all the X electrodes, the potential is repeatedly applied.

Since the X electrodes X1 to X6 of the first detection region 1 and the X electrodes X11 to X16 of the second detection region 2 are individually connected via the connection lines L1 to L6, respectively, the X electrodes X1 to X6 of the first detection region 1 are sequentially selected by the X driver 11 and at the same time the X electrodes X11 to X16 of the second detection region 2 are selected. Accordingly, distributing the potential supplied from the X driver 11 to the X electrodes of the first detection region 1 and the X electrodes of the second detection region 2 is unnecessary and thus the circuit configuration may be simplified.

The predetermined potential generated at the power supply circuit 14 is sequentially supplied to the Y electrodes of the first detection region 1 and the Y electrodes of the second detection region by the Y driver 12. Although not shown, the Y electrode Y1 of the first detection region 1 and the Y electrode Y12 of the second detection region 2 are connected to each other and connected to the Y driver 12 and the Y electrodes Y2 and Y12 are connected to each other and connected to the Y driver 12. Similarly, the electrodes Y3 and Y13, Y4 and Y14, Y5 and Y15, Y6 and Y16, Y7 and Y17, and Y8 and Y18 are respectively connected to each other and connected to the Y driver 12.

Accordingly, the Y electrode Y1 of the first detection region 1 and the Y electrode Y11 of the second detection region 2 are simultaneously selected and supplied with the predetermined potential by the Y driver 12 and then the electrodes Y2 and Y12, Y3 and Y13, Y4 and Y14, Y5 and Y15, Y6 and Y16, Y7 and Y17, and Y8 and Y18 are sequentially selected and supplied with the predetermined potential.

In one embodiment, the application of the potential to the X electrodes and the application of the potential to the Y electrodes are performed at different times and thus the potential is not simultaneously applied to any X electrode and any Y electrode.

In one embodiment, as shown in FIG. 1, in the input device, a data processing unit 15 that detects whether a finger approaches the first detection region 1 and the second detection region 2 and calculating coordinate information of an approaching position of the finger in the first detection region 1 and the second detection region 2 is provided.

The first output line Sa led out of the first detection electrode S1 provided in the first detection region 1 and the second output line Sb led out of the second detection electrode S2 provided in the second detection region 2 are connected to a switching unit 16. The switching unit 16 is controlled by the control unit 13 and the first output line Sa and the second output line Sb are alternately switched and connected to the data processing unit 15.

In one embodiment, a time when the first output line Sa is selected and a time when the second output line Sb is selected by the switching unit 16 are an integral multiple of a time necessary for selecting all the Y electrodes from a time when the Y driver 12 selects the Y electrodes Y1 and Y11 to a time when the Y driver 12 selects the electrodes Y8 and Y18.

An operation of the input device according to the first embodiment will be described.

On the basis of a control operation of the control unit 13, the X electrodes X1 to X6 of the first detection region 1 and the X electrodes X11 to X16 of the second detection region are sequentially selected by the X driver 11. The predetermined potential is simultaneously supplied to the X electrodes of the both detection regions 1 and 2. In the first detection region 1, a voltage is applied between the selected X electrode and the detection electrode S1. In the second detection region 2, a voltage is applied between the selected X electrode and the detection electrode S2. By the Y driver 12, the Y electrodes Y1 to Y8 of the first detection region 1 and the Y electrodes Y11 to Y18 of the second detection region 2 are selected and supplied with the predetermined potential. In the first detection region 1, a predetermined voltage is applied between the selected Y electrode and the detection electrode S1, and, for example, at the same time, in the second detection region 2, a predetermined voltage is applied between the selected Y electrode and the detection electrode S2.

When the finger, which is the conductor, contacts the cover that covers the first detection region 1 and approaches the first detection region 1, the electrostatic field between the detection electrode S1 and the X electrode adjacent to a contact position of the finger varies and the capacitance between the X electrode and the detection electrode S1 is reduced. Accordingly, when the X electrodes which are selected and supplied with the potential are sequentially monitored, the voltage between the detection electrode S1 and the X electrode located at the approaching position of the finger is different from the voltage between the detection electrode S1 and the X electrode located at the non-approaching position of the finger. In this embodiment, for example, when the voltage between the detection electrode S1 and one of the X electrodes located at the approaching position of the finger is compared with the voltage between the detection electrode S1 and the other X electrode, it is possible to detect the approaching position of the finger between the both X electrodes.

Similarly, when the finger contacts the cover that covers the first detection region 1, the electrostatic field between the detection electrode S1 and the Y electrode adjacent to the contact position of the finger varies and thus the capacitance between the detection electrode S1 and the Y electrode is reduced. Accordingly, the voltage between the detection electrode S1 and the Y electrode which is selected and supplied with the potential by the Y driver 12 varies in the Y electrode adjacent to the approaching position of the finger and the Y electrode located at the non-approaching position of the finger.

When the first output line Sa is connected to the data processing unit 15 by the switching unit 16 shown in FIG. 1, the data processing unit 15 can specify an X coordinate position corresponding to the approaching position of the finger in the first detection region 1 and generate X coordinate information by monitoring the voltage between the detection electrode S1 and the X electrodes supplied with the potential in order of the selection of the X electrodes. Similarly, the data processing unit 15 can specify a Y coordinate position corresponding to the approaching position of the finger in the first detection region 1 and generate X coordinate information by monitoring the voltage between the detection electrode S1 and the Y electrodes supplied with the potential by the Y driver 12 in order of the selection of the Y electrodes.

When the potential is applied to the X electrodes and the Y electrodes of the first detection region 1, the potential is applied to the X electrodes and the Y electrodes of the second detection region 2. When the second output line Sb from the detection electrode S2 of the second detection region 2 is connected to the data processing unit 15 by the switching unit 16, the voltage between the detection electrode S2 and the X electrode supplied with the potential is monitored in order of the selection of the X electrodes in the second detection region 2 such that the data processing unit 15 can specify the X coordinate position corresponding to the approaching position of the finger in the second detection region 2 and generate the X coordinate information.

The voltage between the detection electrode S2 and the Y electrode supplied with the potential is monitored in order of the selection of the Y electrodes in the second detection region 2 such that the data processing unit 15 can specify the Y coordinate position corresponding to the approaching position of the finger in the second detection region 2 and generate the Y coordinate information.

In one embodiment, the potential is simultaneously supplied to the X electrodes of the first detection region 1 and the X electrodes of the second detection region 2 by the X driver 11 and the potential is simultaneously supplied to the Y electrodes of the first detection region 1 and the Y electrodes of the second detection region 2 by the Y driver 12. The individual detection electrodes S1 and S2 are provided in the first detection region 1 and the second detection regions 2, respectively, and the outputs of the detection electrodes S1 and S2 are identified and detected in the data processing unit 15.

In one embodiment, timings for switching the first detection electrode S1 and the second detection electrode S2 can be used in the control unit 13 by the switching unit 16.

Accordingly, it is possible to identify whether the finger approaches the first detection region 1 or the second detection region 2. The data processing unit 15 can generate X-Y coordinate information of the approaching position of the finger in the first detection region 1 and X-Y coordinate information of the approaching position of the finger in the second detection region 2. Even when the finger simultaneously approaches the first detection region 1 and the second detection region 2, the data processing unit 15 can generate X-Y coordinate information of the approaching position of the finger in the first detection region 1 and X-Y coordinate information of the approaching position of the finger in the second detection region 2.

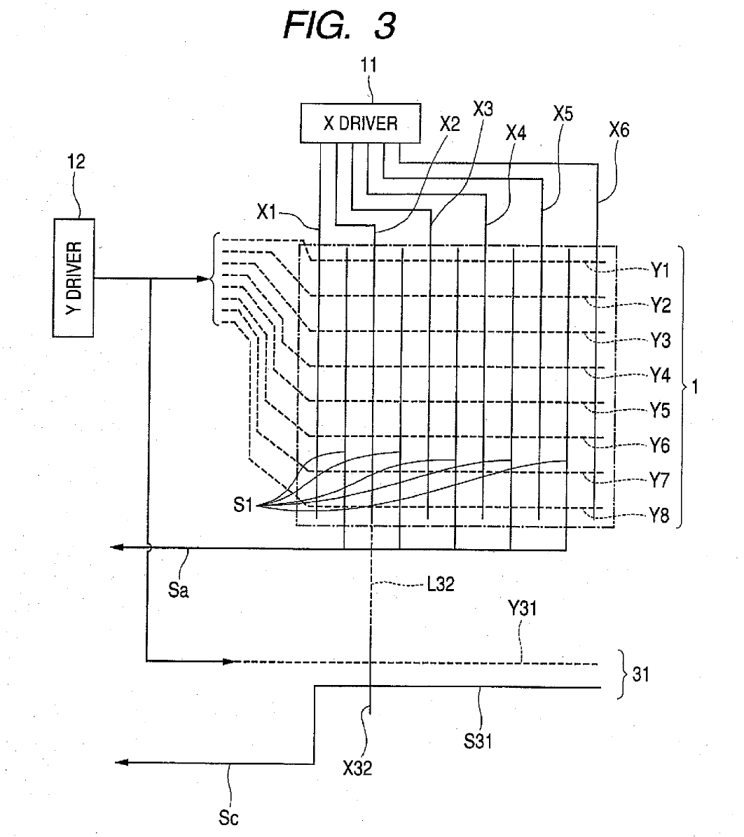

In one embodiment, as shown in FIG. 3, the input device has the same configuration of the first detection region 1 as the input device according to the first embodiment shown in FIGS. 1 and 2. In the input device shown in FIG. 3, a second detection region 31 is provided. The second detection region 31 is provided on the same or different substrate as the first detection region 1.

In the second detection region 31, only one X electrode X32 and one Y electrode Y31 are provided. The X electrode X32 is connected to the X electrode X2 of the first detection region 1 via a connection line L32. The Y electrode Y31 is provided on a surface of the substrate different from a surface on which the X electrode X32 is formed. The Y electrode Y31 is insulated from and perpendicular to the X electrode X32.

In the first detection region 1, a plurality of first detection electrodes S1 are provided and connected to a first output line Sa. In the second detection region 31, one second detection electrode S31 is provided. The second detection electrode S31 is formed parallel to the Y electrode Y31 in the vicinity of the Y electrode Y31. The second detection electrode S33 is formed on the same surface as the Y electrode Y31 and the second detection electrode S31 is insulated from and perpendicular to the X electrode X32.

In one embodiment, when the X electrode X2 of the first detection region 1 is selected by an X driver 11, the X electrode X32 of the second detection region 31 is selected and a potential is simultaneously applied to the X electrode X2 and the X electrode X32. A potential is applied from a Y driver 12 to the Y electrode Y31. After the potential is applied to the Y electrode Y8 of the first detection region 1, the Y electrode Y31 of the second detection region 31 is selected. The potential may be applied to the Y electrode Y31 at a timing different from those of the Y electrodes Y1 to Y8 and the potential may be applied to the Y electrode Y31 and any of the Y electrodes Y1 to Y8.

The first output line Sa, which extends from the first detection electrode S1 of the first detection region 1, and a second output line Sc, which extends from the second detection electrode S31 of the second detection region 31, are alternately switched by the switching unit 16 shown in FIG. 1 and connected to the data processing unit 15.

In one embodiment, as shown in FIG. 3, it is possible to detect whether the finger approaches the first detection region 1 or the second detection region 31. When the finger approaches the first detection region 1, it is possible to recognize to which position of the first detection region 1 the approaching position corresponds in an X-Y coordinate system.

In the second detection region 31, it is possible to detect whether the finger approaches the second detection region 31 by monitoring a variation in capacitance between the Y electrode Y31 and the second detection region S31 when the potential is applied to the Y electrode Y31. It is possible to detect whether the finger which approaches the second detection region reaches the vicinity of the region in which the X electrode X32 is provided by monitoring a variation in capacitance between the X electrode X32 and the second detection electrode S31 when the potential is applied to the X electrode X32. For example, it is possible to determine whether a predetermined switch input is performed in the control unit 13 when it is determined that the finger reaches the vicinity of the X electrode X32.

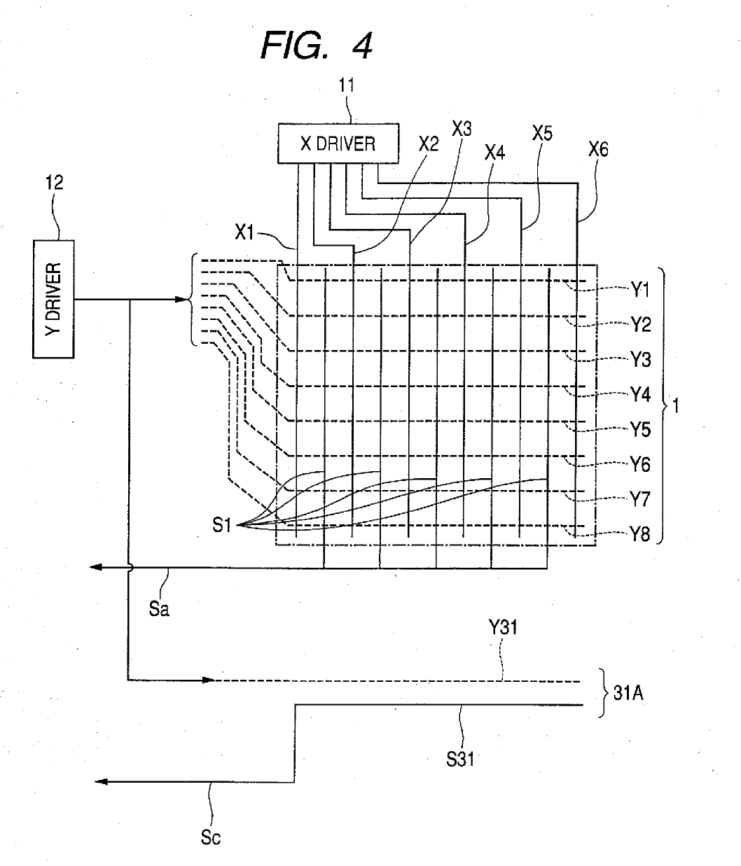

In one embodiment, as shown in FIG. 4, a first detection region 1 is equal to those of the first embodiment and the second embodiment. In a second detection region 31A of the input device shown in FIG. 4, only one Y electrode Y31 and one second detection electrode S31 are provided. In the second detection region 31A, an X electrode is not provided. For example, the structure of the second detection region 31A is equal to that of the second detection region 31 shown in FIG. 3 except the X electrode X32.

In one embodiment, as shown in FIG. 4, when the finger approaches the first detection region 1, it is possible to recognize the approaching position as a position in an X-Y coordinate system. When the finger approaches the second detection region 31A, it is possible to detect only whether the finger contacts a cover that covers the second detection region 31A or not.

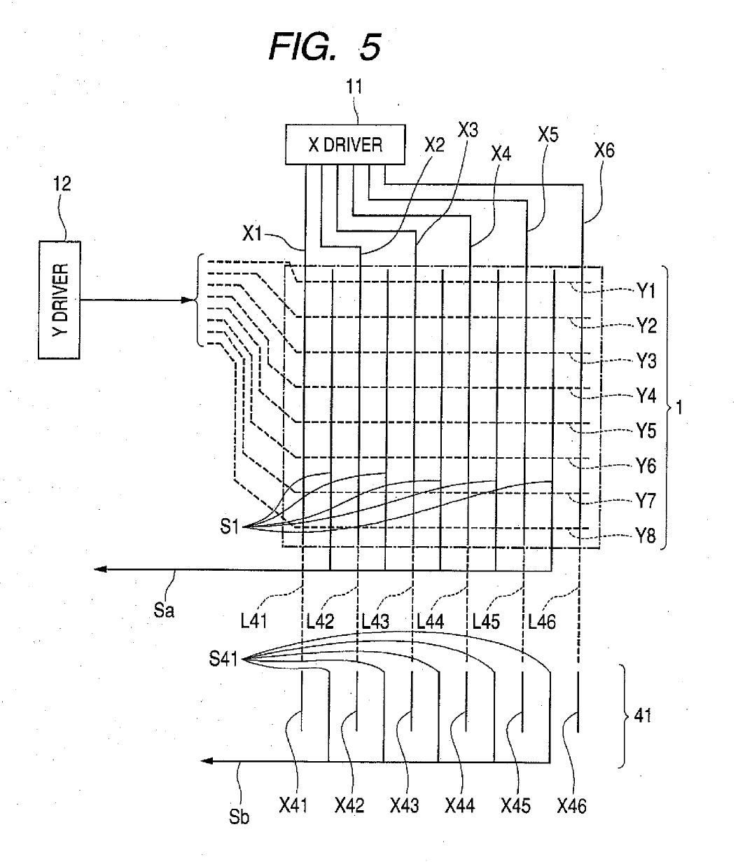

In one embodiment, the structure of a first detection region 1 of the input device shown in FIG. 5 is equal to those of the first detection regions of the above embodiments.

In a second detection region 41 of the input device shown in FIG. 5, a plurality of X electrodes X41, X42, X43, X44, X45 and X46 and a plurality of second detection electrodes S41 located at midpoints between the X electrodes are provided. In the second detection region 41, a Y electrode is not provided. The X electrodes X41 to X46 are individually connected to X electrodes X1 to X6 of the first detection region 1 via connection lines L41 to L46, respectively. Accordingly, the X electrodes X41 to X46 of the second detection region 41 are sequentially selected and supplied with a potential by an X driver 11.

In one embodiment, the plurality of detection electrodes S41 are provided in the second detection region 41 and are connected to one second output line Sd. A first output line Sa, which extends from the first detection electrode S1 of the first detection region 1 and the second output line Sd are switched by a switching unit 16 and connected to a data processing unit 15.

In one embodiment, as shown in FIG. 5, when the finger approaches the first detection region 1, the control unit 13 may recognize the approaching position as a position in an X-Y coordinate system. In the second detection region 41, it can be detected that the finger approaches the detection region 41. Movement information can be obtained when the finger moves in a Y direction (a direction crossing the X electrodes). For example, by monitoring the output from the second detection region 41, the control unit 13 can recognize a slide operation of the finger as the same operation as a linear operation of a variable resistor.

Although the first detection region 1 and the second detection region 2 are provided in the embodiment shown in FIGS. 1 and 2, a third detection region or a fourth detection region may be provided. The X electrodes of each of the detection regions may be connected to the X electrodes X1 to X6, respectively. A potential may be simultaneously applied to the Y electrodes of each of the detection regions by the Y driver 12. Individual detection electrodes may be provided in the third detection region or the fourth detection region.

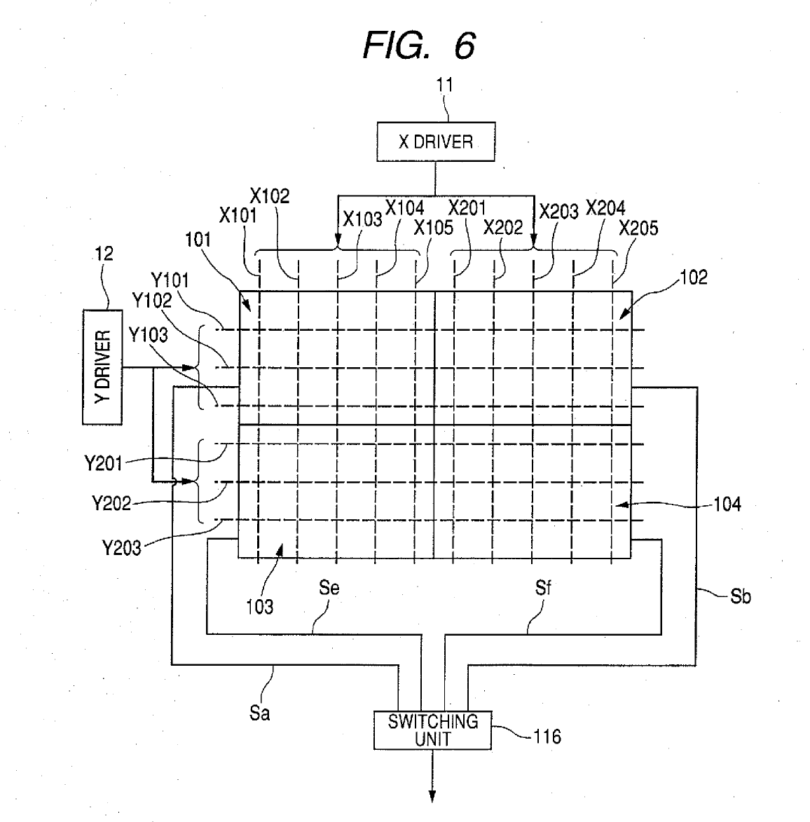

FIG. 6 is an enlarged explanatory view showing an input device according to a fifth embodiment, in which a first detection region to a fourth detection region are provided.

The input device shown in FIG. 6 has a first detection region 101, a second detection region 102, a third detection region 103 and a fourth detection region 104 having the same area. Although the first detection region 101 to the fourth detection region 104 may be formed on different substrates, in the present embodiment, the same substrate (synthetic resin film substrate) is used. The area of the substrate is bisected in a vertical direction and a horizontal direction, for example, divided into four regions such that the first detection region 101 to the fourth detection region 104 are formed.

In one embodiment, on one surface of the substrate, common X electrodes X101, X102, X103, X104 and X105, which extend from the first detection region 101 to the third detection region 103 are provided and common X electrodes X electrodes X201, X202, X203, X204 and X205 are provided in the second detection region 102 and the fourth detection region 104. On the surface of the substrate opposite to the surface on which the X electrodes are formed, common Y electrodes Y101, Y102 and Y103, which extend from the first detection region 101 to the second detection region 102, are provided. Common Y electrodes Y201, Y202 and Y203, which extend from the third detection region 103 and the fourth detection region 104, are provided.

In the first detection region 101, a plurality of first detection electrodes, which are formed at midpoints between adjacent X electrodes, and extend parallel to the X electrodes or a plurality of first detection electrodes, which are formed at midpoints between adjacent Y electrodes and extend parallel to the Y electrodes are provided (the detection electrodes are not shown) and the plurality of first detection electrodes are connected to one another to form a first output line Sa.

In one embodiment, in the second detection region 102, a plurality of second detection electrodes are provided and connected to one another to form a second output line Sb. A third output line Se extends from the third detection region 103 and a fourth output line Sf extends from the fourth detection region 104.

Using an X driver 11, a potential is simultaneously applied to the X electrodes X101 and X201 and then the potential is simultaneously applied to the electrodes X102 and X202. The potential is simultaneously applied to the electrodes X103 and X203, the electrodes X104 and X204 and electrodes X105 and X205 in sequence. Accordingly, the X electrodes of all the regions including the first detection region 101 to the fourth detection region 104 can be simultaneously selected and supplied with the potential.

In one embodiment, the Y electrodes Y101 and Y201, Y102 and Y202, Y103 and Y203 are sequentially selected and supplied with a potential by a Y driver 12. Accordingly, in all the regions including the first detection region 101 to the fourth detection region 104, the Y electrodes are simultaneously selected and sequentially supplied with the potential.

In the first detection region 101 to the fourth detection region 104, the first output line Sa to the fourth output line Sf, which extend from the first detection electrode to the fourth detection electrode provided independently, are sequentially selected by a switching unit 116 and connected to a data processing unit 15.

In one embodiment, when the finger approaches any of the first detection region 101 to the fourth detection region 104, the data processing unit 105 can recognize which region the finger approaches and obtain X-Y coordinate information of the approaching position of the finger.

The first detection region 101 to the fourth detection region 104 can be used by a successive integral operation region. In this embodiment, although the area of the operation region is wide, it is possible to reduce the number of electrodes driven by the X driver 11 and the Y driver 12. For example, the X driver 11, which can select the X electrodes by a quarter of the total number of the X electrodes provided in the four detection regions and supply a potential to the X electrode, may be provided. The Y driver 12, which can select the Y electrodes by a quarter of the total number of the Y electrodes provided in the four detection regions and supply a potential to the Y electrodes, may be provided. In the same operation region, although the finger simultaneously approaches different detection regions, it is possible to obtain coordinate data of the approaching positions of the finger.

The input device according to the present embodiments may be mounted in a variety of apparatuses.

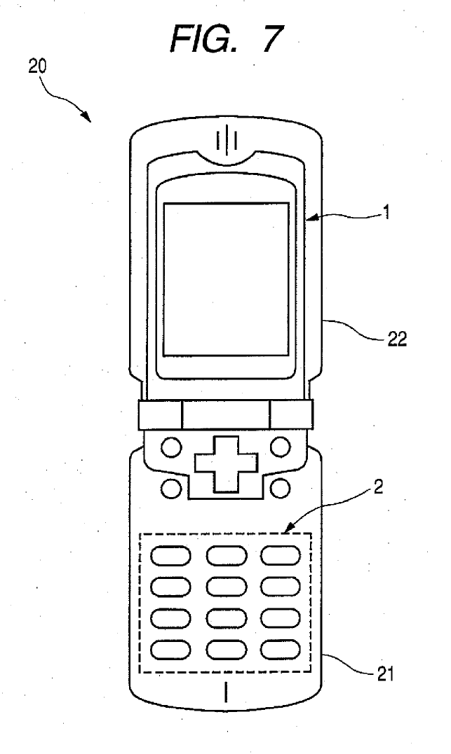

For example, in the input device according to the first embodiment shown in FIG. 2, the second detection region 2 is disposed on the inside of a casing in an operation surface of a main body unit 21 of a mobile phone 20 shown in FIG. 7 and the first detection region 1 is disposed on the inside of a transparent plate of a display screen of a display unit 22. The first and second detection regions may be disposed on the side surface or the rear surface of the main body 21 and the side surface or the rear surface of the display unit 22, respectively.

In the input devices according to the second to fourth embodiments shown in, for example, FIGS. 3 to 5, the first detection region 1 may be disposed in the operation surface of the main body unit 21 or the display unit 22 and the second detection regions 21, 31A and 41 may be in the side surface of the main body unit 21 or the side surface of the display unit 22.

As the mobile terminal, the input device may be mounted in a small-sized game apparatus, a car navigation apparatus or an audio-apparatus in addition to the mobile terminal.

In the input device according to the fifth embodiment shown in FIG. 6, the detection region may be disposed in an office apparatus having a relatively wide operation surface.

Although the substrate is the resin film substrate in the above embodiments, the substrate may be a non-flexible substrate having high rigidity.

Various embodiments described herein can be used alone or in combination with one another. The forgoing detailed description has described only a few of the many possible implementations of the present invention. For this reason, this detailed description is intended by way of illustration, and not by way of limitation. It is only the following claims, including all equivalents that are intended to define the scope of this invention.

1. An input device comprising:
a plurality of detection regions,
an X electrode and a Y electrode, which are insulated from and perpendicular to each other, in each of the plurality of detection regions,
an X driver that is operative to select the X electrode in the plurality of detection regions and supply a potential to the X electrode,
a Y driver that is operative to select the Y electrode in the plurality of detection regions and supply a potential to the Y electrode, and
detection electrodes, which are independent of each other in the detection regions,
wherein a variation in a capacitance field between the X electrode supplied with the potential and the detection electrode and a variation in a capacitance field between the Y electrode supplied with the potential and the detection electrode are individually detected in each of the detection regions by the detection electrode.

2. The input device according to claim 1, wherein the X electrode and the Y electrode are provided in plural in at least one of the detection regions.

3. An input device comprising:
at least one first detection region and a second detection region,
a plurality of X electrodes and Y electrodes, which are insulated from and perpendicular to each other, in the first detection region and one of an X electrode and a Y electrode is provided in the second detection region,
an X driver that is operative to select the X electrode in the first detection region and supply a potential to the X electrode, and
a Y driver that is operative to select the Y electrode in the second detection region and supply a potential to the Y electrode,
wherein a potential is supplied from the X driver to the X electrode provided in the second detection region and a potential is applied from the Y driver to the Y electrode provided in the second detection region,
wherein detection electrodes, which are independent of each other, are provided in the first detection region and the second detection region, and
wherein a variation in the capacitance field between the X electrode supplied with the potential and the detection electrode and a variation in the capacitance field between the Y electrode supplied with the potential and the detection electrode are detected in the first detection region and a variation in capacitance field between the X electrode supplied with the potential and the detection electrode or a variation in capacitance field between the Y electrode supplied with the potential and the detection electrode is detected in the second detection region.

4. The input device according to claim 3, wherein the X electrode and the Y electrode are provided in plural in the first detection region.

5. The input device according to claim 1, wherein X electrodes in different detection regions are simultaneously selected and supplied with the potential by the X driver.

6. The input device according to claim 1, wherein Y electrodes in different detection regions are simultaneously selected and supplied with the potential by the Y driver.

7. The input device according to claim 1, wherein the detection regions are provided on different substrates or a same substrate, the X electrode is provided on one surface of the substrate and the Y electrode is provided on the other surface of the substrate, and the detection electrodes are provided on the one surface or the other surface.

8. The input device according to claim 1, wherein a data processing unit that generates positional information of a detection region which an operation body of a conductor approaches and an approaching position of the operation body in the detection region from the variation in capacitance field between the X electrode supplied with the potential and the detection electrode and the variation in capacitance field between the Y electrode supplied with the potential and the detection electrode is provided.

9. The input device according to claim 8, wherein a switching unit that sequentially selects the detection electrodes, which are independently provided in the detection regions and connecting the detection electrodes to the data processing unit, is provided.

10. The input device according to claim 1, wherein the X electrodes in different detection regions are connected to one another.

11. The input device according to claim 1, wherein the Y electrodes in different detection regions are connected to one another.
